(19) United States
(12) Patent Application Publication
(10) Pub. No.: US 2014/0063667 A1
(43) Pub. Date: Mar. 6, 2014

(54) ACTIVE CLAMP FOR A SEMICONDUCTOR SWITCH

(71) Applicant: ABB OY, Helsinki (FI)

(72) Inventor: Mikko SAARINEN, Helsinki (FI)

(73) Assignee: ABB OY, Helsinki (FI)

(21) Appl. No.: 14/020,533

(22) Filed: Sep. 6, 2013

(30) Foreign Application Priority Data
Sep. 6, 2012 (EP) 12183255.4

(51) Int. Cl. H01L 23/62

(52) U.S. Cl. CPC H01L 23/62
USPC 361/56

(57) ABSTRACT

Exemplary embodiments are directed to a method and arrangement for detecting an overvoltage of a semiconductor switch. The arrangement including a first semiconductor switch and a driver unit controlling the switch. An overvoltage is detected over the semiconductor switch, and a voltage is adjusted at a supply voltage input of the driver unit on the basis of the overvoltage.

### RELATED APPLICATION

This application claims priority under 35 U.S.C. §119 to European Application 12183255.4 filed in Europe on Sep. 6, 2012, the content of which is hereby incorporated by reference in its entirety.

### FIELD

The disclosure relates to semiconductor switches, and particularly to controlling surge voltages over semiconductor switches.

### BACKGROUND INFORMATION

Semiconductor switches (IGBT, MOSFET, etc.) are widely used. These uses can include power electronics. The switches can be adapted to operate in one of two states: a conducting state and a non-conducting state. A driver unit can be used to control the switch to one state or the other. To accomplish this, the driver unit supplies a control signal to a control terminal of the switch. In the case of, for example, an IGBT switch, the control signal can be a voltage which is supplied to the gate terminal of the IGBT switch.

In simplified terms, the control signal has two levels: one for the conducting state of the switch and another for the non-conducting state of the switch. In the conducting state, the current can flow through the switch, while in the non-conducting state the current is not able to flow as the switch is in a high-impedance state. The switch can be set from one state to another by changing the control signal from one level to the other.

In practice, however, changing the state of the switch can be more complex. For example, turning off a semiconductor switch when it is driving a high current inductive load can induce a shut-off voltage surge which can damage the switch.

In order to safely turn off the switch, a rate of the turn-off of the switch can be controlled by adjusting the control signal controlling the switch. The switch can, for example, be controlled with an external driver unit which detects a high current during the turn-off. When the high current is detected, the driver unit can select a slower turn-off rate for the control signal. Applying a slower rate of change of the control signal can reduce a rate of change in the current flowing through the switch, which, in turn, can reduce a peak voltage of the voltage surge. However, detecting the high current and changing to a slower turn-off rate is not instantaneous. While detecting the high current and changing to the slower turn-off rate, the surge voltage can be able to rise to an excessively high level.

Another approach is to drive a gate voltage of a semiconductor switch directly to the collector-emitter voltage of the switch when a voltage surge occurs. This can reduce the rate of change of the gate voltage. This reduces the rate of change in the current, which, in turn, reduces the peak voltage of the voltage surge. During a voltage surge, the collector-emitter voltage can, for example, drive the gate voltage directly through zener diodes and resistors, thus, allowing a faster reaction to the surge voltage. However, this approach can also cause high power losses as two sources try to drive the gate voltage to two different voltages.

### SUMMARY

An exemplary arrangement for clamping an overvoltage of a semiconductor is disclosed, comprising: a first semiconductor switch having a first terminal, a second terminal, and a third terminal, wherein the first switch is configured to control a current between the first terminal and second terminal on the basis of a control signal supplied to the third terminal, wherein the control signal has a first level for controlling the first switch to a conducting state and a second level for controlling the first switch to a non-conducting state; a driver unit including an output providing the control signal to the third terminal of the first switch, a first supply voltage input for providing an upper limit level of an operational range of the control signal, and a second supply voltage input for providing a lower limit level of the operational range of the control signal; means for supplying a first voltage to the first supply voltage input and a second voltage to the second supply voltage input; means for determining an overvoltage between the first terminal and the second terminal of the first switch; and means for adjusting the voltage at the second supply voltage input on the basis of the overvoltage between the first terminal and the second terminal of the first switch.

An exemplary method for clamping an overvoltage of a semiconductor using an arrangement is disclosed. The semiconductor includes a first semiconductor switch having a first terminal, a second terminal, and a third terminal, wherein the first switch is adapted to control a current between the first terminal and second terminal on the basis of a control signal supplied to the third terminal, wherein the control signal has a first level for controlling the first switch to a conducting state and a second level for controlling the first switch to a non-conducting state; a driver unit having an output providing the control signal to the third terminal of the first switch, a first supply voltage input for providing an upper limit level of an operational range of the control signal, and a second supply voltage input for providing a lower upper limit level of an operational range of the control signal; and means for supplying a first voltage to the first supply voltage input and a second voltage to the second supply voltage input, the method comprising: determining an overvoltage between the first terminal and the second terminal of the first switch; and adjusting the voltage at the second supply voltage input on the basis of the overvoltage between the first terminal and the second terminal of the first switch.

### BRIEF DESCRIPTION OF THE DRAWINGS

In the following, the disclosure will be described in greater detail by means of exemplary embodiments with reference to the attached drawings, in which

FIG. 1 is a block diagram illustrating a method for clamping an overvoltage of a semiconductor switch and adjusting a control signal of the switch based on the overvoltage in accordance with an exemplary embodiment of the present disclosure;

FIG. 2 illustrates a first arrangement for clamping an overvoltage of a semiconductor in accordance with an exemplary embodiment of the present disclosure; and

FIG. 3 illustrates a second arrangement for clamping an overvoltage of a semiconductor in accordance with an exemplary embodiment of the present disclosure.

### DETAILED DESCRIPTION

Exemplary embodiments of the present disclosure provide a method and an arrangement for detecting an overvoltage of a semiconductor switch and adjusting a control signal of the switch based on the overvoltage to alleviate the above disadvantages.

The disclosed method and arrangement detect an overvoltage over the semiconductor switch (IGBT, MOSFET, etc.), and adjust a control signal controlling the switch on the basis of the overvoltage. The overvoltage can, for example, be detected by comparing the collector-emitter voltage of a switch to a set voltage limit. When the limit is exceeded, the disclosed method and arrangement adjust the voltage at a driver unit supply voltage input used for generating the off-state of the control signal. The voltage at the supply voltage input can, for example, be adjusted by controlling the impedance between the supply voltage input and a power source supplying the input. The impedance can be adjusted, for example, by placing a semiconductor switch in parallel with a resistor in the path between the power source and the supply input. Alternatively, the voltage can be adjusted by simply disconnecting the source.

In this manner, the exemplary method and apparatus disclosed herein are able to quickly react to a voltage surge. Since only the driver unit drives the control signal, the power consumption can be kept at a relatively low level. The disclosed method and apparatus can be implemented in a cost-effective manner. The driver unit controlling the semiconductor switch can be a simple gate driver unit without high current detection.

In order to avoid damage to the switch caused by a voltage surge, the disclosed method can first detect an overvoltage over the semiconductor switch. A control signal controlling the switch can then be adjusted, on the basis of the overvoltage.

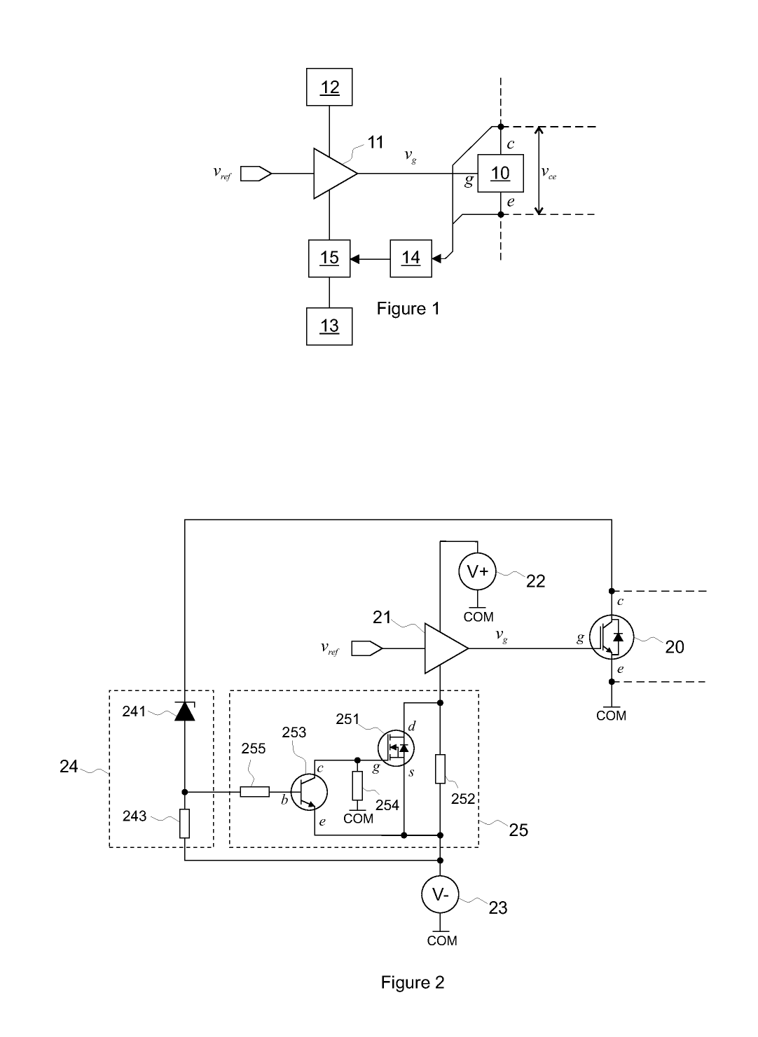

FIG. 1 is a simplified block diagram illustration of a method for clamping an overvoltage of a semiconductor switch and adjusting a control signal of the switch based on the overvoltage in accordance with an exemplary embodiment. The arrangement in FIG. 1 includes (e.g., comprises) a first semiconductor switch 10, and a driver unit 11. In FIG. 1, the semiconductor switch 10 has (e.g., comprises) a first terminal c, a second terminal e, and a third terminal g. The first switch 10 is adapted to control a current between the first terminal c and second terminal e on the basis of a control signal v_{g} supplied to the third terminal g. The control signal v_{g} has a first level for controlling the first switch 10 to a conducting state and a second level for controlling the first switch 10 to a non-conducting state.

The driver unit 11 includes an output providing the control signal v_{g} to the third terminal g of the first switch 10, a first supply voltage input v_{cc} for providing an upper limit level of an operational range of the control signal v_{g}, and a second supply voltage input vₑₑ for providing a lower limit level of the operational range of the control signal v_{g}. The level of the control signal v_{g} can thus vary between the upper and lower limit levels. The control signal v_{g} is controlled on the basis of a reference signal v_{ref}. In order for the driver unit 11 to be able to produce the control signal levels, the arrangement in FIG. 1 further includes means for supplying a first voltage to the first supply voltage input and a second voltage to the second supply voltage input. In FIG. 1, these means are power supplies 12 and 13 which are connected to first and second supply voltage inputs, respectively.

The arrangement in FIG. 1 further includes means 14 for determining an overvoltage between the first terminal c and the second terminal e of the first switch 10, and means 15 for adjusting the voltage at the second supply voltage input on the basis of the overvoltage between the first terminal c and the second terminal e of the first switch 10.

The means 14 for determining the overvoltage can, for example, include means for comparing a voltage v_{ce} between the first terminal c and the second terminal e to a set voltage level, and means for producing an overvoltage detection signal on the basis of the comparison. In one simple form, the comparison can be accomplished by a circuitry where a zener diode is connected between the first terminal c and the second terminal e of the first switch 10. The circuitry is configured such that when the voltage v_{ce} between the first terminal c and the second terminal e rises above the breakdown voltage of the zener diode, the zener diode starts to conduct current. The current through the zener diode can then be used for producing an indicator signal indicating overvoltage.

The disclosed method is not limited to the above implementation of the means for determining the overvoltage. Other implementations can also be used. The overvoltage can, for example, be detected by using a comparator circuit which compares the voltage v_{ce} between the first terminal c and the second terminal e with a reference voltage.

The means 15 for adjusting the second voltage can, for example, include means for adjusting an impedance of a connection between the second voltage supply input and the means for supplying the second voltage on the basis of the overvoltage between the first terminal and the second terminal. The impedance can, for example, be adjusted by placing a second semiconductor switch in parallel with a resistor in the path between the means 13 for supplying the second voltage and the second voltage supply input vₑₑ.

Alternatively, the means 15 for adjusting the second voltage can include means for disconnecting a connection between the second voltage supply input and the means 13 for supplying the second voltage on the basis of the overvoltage between the first terminal and the second terminal.

The means for adjusting in disclosed method are not limited to the above implementations. Other implementations can also be used.

FIG. 2 illustrates a first arrangement for clamping an overvoltage of a semiconductor in accordance with an exemplary embodiment of the present disclosure The arrangement has a first switch, e.g., an IGBT 20, and a driver unit, such as a gate driver unit 21. The IGBT switch has a first terminal, e.g., a collector terminal c, a second terminal, e.g., an emitter terminal e, and a third terminal, e.g., a gate terminal g. A current between the collector terminal c and the emitter terminal e is controlled on the basis of a control signal supplied to the gate terminal g. In FIG. 2, the control signal is a control voltage v_{g} which has a first level for driving the IGBT 20 to a conducting state and a second level for driving the IGBT 20 to a non-conducting state.

The gate driver unit 21 includes an output providing the control voltage to the gate terminal g of the IGBT 20. The gate driver unit 21 is connected to the gate terminal g of the IGBT 20. In the embodiment of FIG. 2, the gate driver unit 21 can also have a gate resistor. The gate driver unit 21 controls the level of the control signal v_{g} on the basis of a reference signal v_{ref} which the gate driver unit 21 receives as a voltage at its reference input terminal.

The gate driver unit further includes a first supply voltage input v_{cc} for providing an upper voltage level which can be used for producing the first level of the control voltage v_{g}, and a second supply voltage input vₑₑ for providing an lower voltage level which can be used for producing the second level of the control voltage v_{g}. A positive voltage source 22 and a negative voltage source 23 act as means for supplying a first voltage to the first supply voltage input v_{cc} and a second voltage to the second supply voltage input vₑₑ, respectively. The positive voltage source 22 and the negative voltage source 23 are connected to the common ground COM which is also connected to the second terminal of the IGBT 20.

In FIG. 2, the arrangement further includes means 24 for determining an overvoltage between the collector terminal c and the emitter terminal e of the IGBT 20, and means 25 for adjusting the voltage at the second supply voltage input vₑₑ on the basis of the overvoltage between the collector terminal c and the emitter terminal e of the IGBT 20.

The means 24 for determining an overvoltage are implemented by a series connection of a zener diode 241 and a resistance 242 between the collector terminal c and the emitter terminal e of the IGBT 20. The zener diode 241 acts as the means for comparing the voltage between the first terminal and the second terminal, e.g, the collector-emitter voltage v_{ce}, to a set voltage level, while the resistor 242 acts as the means for producing an overvoltage detection signal on the basis of the comparison. The zener diode 241 is configured to conduct current when the collector-emitter voltage v_{ce} exceeds a set voltage level, and the resistance 242 is configured to produce an overvoltage detection voltage vₒᵥ responsive to the current through the zener diode 241.

In FIG. 2, the series connection is connected between the collector terminal c and the emitter terminal e of the IGBT 20 through the negative voltage source 23 and the common ground COM. In other words, the set voltage, e.g., breakdown voltage of zener diode 241, can be the difference between a desired overvoltage indication level for the collector-emitter voltage v_{ce} and the voltage of the negative voltage source 23.

In FIG. 2, the means 25 for adjusting the voltage at the second supply voltage input vₑₑ are implemented by a parallel connection of a second semiconductor switch 251 and a resistance 252 between the second supply voltage input and the negative voltage source 23. In FIG. 2, the second semiconductor switch 251 is an N-channel MOSFET having a source terminal, a drain terminal and a gate terminal. The parallel connection acts as means for adjusting the impedance of the connection between the second supply voltage input and the negative voltage source 23.

By using the parallel connection, the resistance between the second supply voltage input vₑₑ of the gate driver unit 21 and the negative voltage source 23 can be adjusted on the basis of the collector-emitter voltage v_{ce} of the IGBT 20. The second switch 251 can be configured to switch between a conducting state and a non-conducting state responsive to the collector-emitter voltage v_{ce} of the IGBT 20 in such a manner that when the collector-emitter voltage v_{ce} exceeds a set voltage level, the second switch 251 switches into a non-conducting state.

When the second switch 251 switches into the non-conducting state, the resistance of the connection between the second supply voltage input vₑₑ and the negative voltage source 23 increases. The increase in the resistance slows the rate of change of the voltage at the gate terminal of the first switch 20. The slower rate of change can then reduce the voltage surge between the first terminal and the second terminal of the first switch 20.

As illustrated in FIG. 2, a third semiconductor switch 253 can be used for controlling the second switch 251 on the basis of the overvoltage. The third switch 253 is connected in parallel with a resistor 254 to a gate terminal of the second switch 251 in order to control a gate-source voltage, e.g., a voltage between the gate terminal and the source terminal of the second switch 251. In FIG. 2, the third semiconductor switch 253 is an NPN-type BJT. The base of the third semiconductor 253 is connected to the interconnection between the zener diode 241 and the resistor 242 through a base resistor 255.

When the collector-emitter voltage v_{ce} does not exceed a maximum voltage set for it, the zener diode 241 does not conduct current. Therefore, there is no voltage difference between the base terminal and the emitter terminal of the third switch 253, e.g., the base-emitter voltage of the third switch is zero, and no current through the base terminal of the third switch 253. The third switch 253 is, thus, in non-conducting state. As a result, the resistor 254 is able to pull the voltage between the gate and the source, e.g., the gate-source voltage v_{ge}, of the second switch 251 to a level which drives the second switch 251 to a conducting state. The second switch 251 in the conducting state provides a low-impedance route between the second supply voltage input vₑₑ and the negative voltage source 23.

When the collector-emitter voltage v_{ce} exceeds a set maximum voltage, the zener diode 241 starts to conduct, and a current through the zener diode 241 and the resistor 242 generates a base-emitter voltage vₒᵥ which sets the third switch 253 to a conducting state. As a result, the gate-source voltage of the second switch 251 is driven to zero. As a result, the second switch 251 switches into the non-conducting state, and the resistance of the connection between the second supply voltage input vₑₑ and the negative voltage source 23 increases.

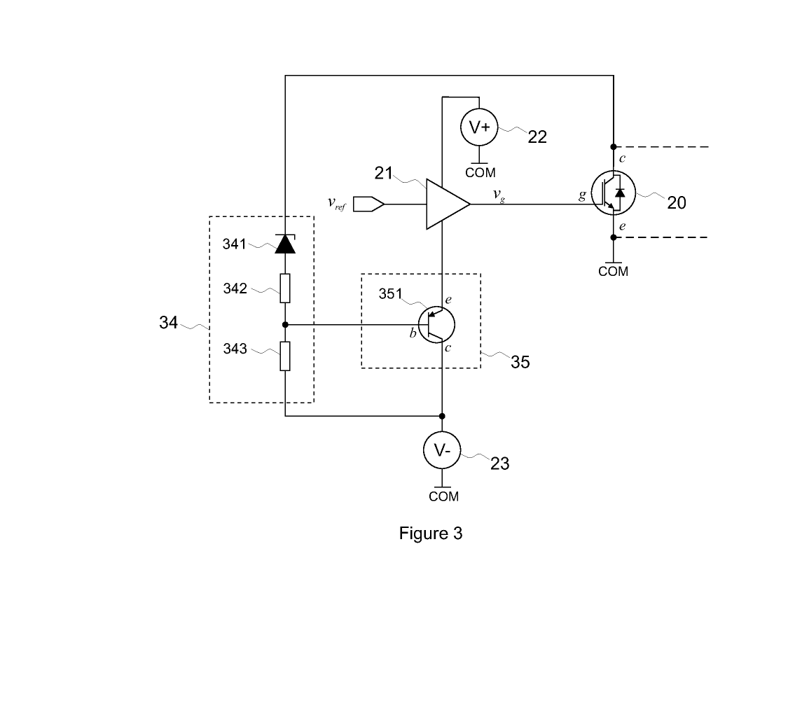

FIG. 3 illustrates another second arrangement for clamping an overvoltage of a semiconductor in accordance with an exemplary embodiment of the present disclosure. The exemplary arrangement of FIG. 3 differs from the arrangement of FIG. 2 by its means 34 for determining an overvoltage and by its means 35 for adjusting the voltage at the second supply voltage input vₑₑ of the gate driver unit 21.

In FIG. 3, the means 34 for determining an overvoltage are implemented by a series connection of a zener diode 341 and two resistances 342 and 343 between the collector terminal c and the emitter terminal e of the IGBT 20. The zener diode 341 acts as the means for comparing the voltage between the first terminal and the second terminal, e.g., the collector-emitter voltage v_{ce}, to a set voltage level, while the resistors 342 and 343 acts as the means for producing an overvoltage detection signal on the basis of the comparison.

In FIG. 3, the means 35 for adjusting the voltage at the second supply voltage input vₑₑ are implemented by a second semiconductor switch 351 between the second supply voltage input vₑₑ and the negative voltage source 23. In the arrangement of FIG. 3, the second switch 351 is a PNP-type BJT which is directly controlled by the means 34 for determining an overvoltage. The base terminal of the second switch 351 is connected to the interconnection between the two resistances 342 and 343 of the means 34 for determining the overvoltage.

When the collector-emitter voltage v_{ce} of the IGBT 20 does not exceed a maximum voltage set for it, the zener diode 341 does not conduct current. Therefore, a voltage between an emitter terminal and a base terminal, e.g., an emitter-base voltage, of the second switch 351 is at a level which drives the second switch 351 into saturation region. Thus, the second switch 351 provides a low-impedance path between the second supply voltage input vₑₑ and the negative voltage source 23.

When the collector-emitter voltage v_{ce} of the IGBT 20 exceeds the set voltage limit, the zener diode 341 starts to conduct, and a current through the zener diode 341 and the resistors 342 and 343 generates a voltage vₒᵥ over the resistor 343. The voltage vₒᵥ over the resistor 343 reduces the emitter-base voltage of the second switch 351 such that the second switch 351 switches into active region and a voltage difference between the second supply voltage input vₑₑ and the negative voltage source 23 increases.

It should be apparent to a person skilled in the art that the exemplary embodiments described herein can be implemented in various ways. As such, the disclosure and its embodiments are not limited to the examples described above but can vary within the scope of the claims. For example, in FIGS. 2 and 3, the transistors in the means 25 and 35 for adjusting voltage at the second supply voltage input can, for example, be replaced with other kind of semiconductor switches.

The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

What is claimed is:

1. An arrangement for clamping an overvoltage of a semiconductor, comprising:
a first semiconductor switch having a first terminal, a second terminal, and a third terminal, wherein the first switch is configured to control a current between the first terminal and second terminal on the basis of a control signal supplied to the third terminal, wherein the control signal has a first level for controlling the first switch to a conducting state and a second level for controlling the first switch to a non-conducting state;
a driver unit including an output providing the control signal to the third terminal of the first switch, a first supply voltage input for providing an upper limit level of an operational range of the control signal, and a second supply voltage input for providing a lower limit level of the operational range of the control signal;
means for supplying a first voltage to the first supply voltage input and a second voltage to the second supply voltage input;
means for determining an overvoltage between the first terminal and the second terminal of the first switch; and
means for adjusting the voltage at the second supply voltage input on the basis of the overvoltage between the first terminal and the second terminal of the first switch.

2. The arrangement according to claim 1, wherein the means for determining an overvoltage comprises:
means for comparing the voltage between the first terminal and the second terminal of the first switch with a set voltage level; and
means for producing an overvoltage detection signal on the basis of the comparison.

3. The arrangement according to claim 1, comprising:
a series connection of a zener diode and a resistance between the first terminal and the second terminal of the first switch, wherein the zener diode is configured to conduct current when the voltage between the first terminal and the second terminal exceeds the set voltage level, and the resistance is configured to produce an overvoltage detection voltage responsive to the current through the zener diode.

4. The arrangement according to claim 2, comprising:
a series connection of a zener diode and a resistance between the first terminal and the second terminal of the first switch, wherein the zener diode is configured to conduct current when the voltage between the first terminal and the second terminal exceeds the set voltage level, and the resistance is configured to produce an overvoltage detection voltage responsive to the current through the zener diode.

5. The arrangement according to claim 1, comprising:
a series connection of a zener diode and two resistances between the first terminal and the second terminal of the first switch, wherein the zener diode is configured to conduct current when the voltage between the first terminal and the second terminal exceeds the set voltage level, and the two resistances are configured to produce an overvoltage detection voltage responsive to the current through the zener diode.

6. The arrangement according to claim 2, comprising:
a series connection of a zener diode and two resistances between the first terminal and the second terminal of the first switch, wherein the zener diode is configured to conduct current when the voltage between the first terminal and the second terminal exceeds the set voltage level, and the two resistances are configured to produce an overvoltage detection voltage responsive to the current through the zener diode.

7. The arrangement as claimed in claim 1, wherein the means for adjusting the second voltage comprises:
means for adjusting an impedance of a connection between the second supply voltage input and the means for supplying the second voltage on the basis of the overvoltage between the first terminal and the second terminal of the first switch.

8. The arrangement as claimed in claim 1, wherein the means for adjusting the voltage at the second supply voltage input comprises:
a parallel connection of a second semiconductor switch and a resistance in between the second supply voltage input and the means for supplying the second voltage, wherein the second switch is configured to switch between a conducting state and a non-conducting state responsive to a voltage between the first terminal and the second terminal of the first switch in such a manner that when the voltage between the first terminal and the second terminal of the first switch exceeds the set voltage level, the second switch switches into a non-conducting state.

9. The arrangement as claimed in claim 1, wherein the means for adjusting the voltage at the second supply voltage input comprises:
a second semiconductor switch between the second supply voltage input and the means for supplying the second voltage, wherein the second switch is configured to switch between saturation region and active region responsive to a voltage between the first terminal and the second terminal of the first switch in such a manner that when the voltage between the first terminal and the second terminal of the first switch exceeds the set voltage level, the second switch switches into active region.

10. The arrangement as claimed in claim 1, wherein the means for adjusting the voltage at the second supply voltage input comprises:
means for disconnecting a connection between the second supply voltage input and the means for supplying the second voltage on the basis of the overvoltage between first terminal and the second terminal of the first switch.

11. The arrangement as claimed in claim 2, wherein the means for adjusting the second voltage comprises:
means for adjusting an impedance of a connection between the second supply voltage input and the means for supplying the second voltage on the basis of the overvoltage between the first terminal and the second terminal of the first switch.

12. The arrangement as claimed in claim 2, wherein the means for adjusting the voltage at the second supply voltage input comprises:
a parallel connection of a second semiconductor switch and a resistance in between the second supply voltage input and the means for supplying the second voltage, wherein the second switch is configured to switch between a conducting state and a non-conducting state responsive to a voltage between the first terminal and the second terminal of the first switch in such a manner that when the voltage between the first terminal and the second terminal of the first switch exceeds the set voltage level, the second switch switches into a non-conducting state.

13. The arrangement as claimed in claim 2, wherein the means for adjusting the voltage at the second supply voltage input comprises:
a second semiconductor switch between the second supply voltage input and the means for supplying the second voltage, wherein the second switch is configured to switch between saturation region and active region responsive to a voltage between the first terminal and the second terminal of the first switch in such a manner that when the voltage between the first terminal and the second terminal of the first switch exceeds the set voltage level, the second switch switches into active region.

14. The arrangement as claimed in claim 2, wherein the means for adjusting the voltage at the second supply voltage input comprises:
means for disconnecting a connection between the second supply voltage input and the means for supplying the second voltage on the basis of the overvoltage between first terminal and the second terminal of the first switch.

15. The arrangement as claimed in claim 3, wherein the means for adjusting the second voltage comprises:
means for adjusting an impedance of a connection between the second supply voltage input and the means for supplying the second voltage on the basis of the overvoltage between the first terminal and the second terminal of the first switch.

16. The arrangement as claimed in claim 3, wherein the means for adjusting the voltage at the second supply voltage input comprises:
a parallel connection of a second semiconductor switch and a resistance in between the second supply voltage input and the means for supplying the second voltage, wherein the second switch is configured to switch between a conducting state and a non-conducting state responsive to a voltage between the first terminal and the second terminal of the first switch in such a manner that when the voltage between the first terminal and the second terminal of the first switch exceeds the set voltage level, the second switch switches into a non-conducting state.

17. The arrangement as claimed in claim 3, wherein the means for adjusting the voltage at the second supply voltage input comprises:
a second semiconductor switch between the second supply voltage input and the means for supplying the second voltage, wherein the second switch is configured to switch between saturation region and active region responsive to a voltage between the first terminal and the second terminal of the first switch in such a manner that when the voltage between the first terminal and the second terminal of the first switch exceeds the set voltage level, the second switch switches into active region.

18. The arrangement as claimed in claim 3, wherein the means for adjusting the voltage at the second supply voltage input comprises:
means for disconnecting a connection between the second supply voltage input and the means for supplying the second voltage on the basis of the overvoltage between first terminal and the second terminal of the first switch.

19. The arrangement as claimed in claim 4, wherein the means for adjusting the second voltage comprises:
means for adjusting an impedance of a connection between the second supply voltage input and the means for supplying the second voltage on the basis of the overvoltage between the first terminal and the second terminal of the first switch.

20. A method for clamping an overvoltage of a semiconductor using an arrangement that includes:
a first semiconductor switch having a first terminal, a second terminal, and a third terminal, wherein the first switch is adapted to control a current between the first terminal and second terminal on the basis of a control signal supplied to the third terminal, wherein the control signal has a first level for controlling the first switch to a conducting state and a second level for controlling the first switch to a non-conducting state;
a driver unit having an output providing the control signal to the third terminal of the first switch, a first supply voltage input for providing an upper limit level of an operational range of the control signal, and a second supply voltage input for providing a lower upper limit level of an operational range of the control signal; and
means for supplying a first voltage to the first supply voltage input and a second voltage to the second supply voltage input, the method comprising:
determining an overvoltage between the first terminal and the second terminal of the first switch; and
adjusting the voltage at the second supply voltage input on the basis of the overvoltage between the first terminal and the second terminal of the first switch.
